(19) United States
(12) Patent Application Publication
(10) Pub. No.: US 2009/0166864 A1
(43) Pub. Date: Jul. 2, 2009

(54) METHOD TO PREVENT COPPER MIGRATION IN A SEMICONDUCTOR PACKAGE

(76) Inventors: Mengzhi Pang, Phoenix, AZ (US); Isao Yamada, Tokyo (JP)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 11/966,727

(22) Filed: Dec. 28, 2007

(51) Int. Cl. H01L 21/768; H01L 23/538

(52) U.S. Cl. 257/751; 438/653; 257/E21.584; 257/E23.169

(57) ABSTRACT

A semiconductor package comprises a semiconductor die, a substrate that is coupled to the die, a trace formed in the substrate that comprises a first conductive material, e.g., copper, doped with a second conductive material, e.g., aluminum, the first conductive material has a first diffusivity that is lower than a second diffusivity of the second conductive material to prevent migration of the first conductive material.

### BACKGROUND

A semiconductor package may comprise one or more semiconductor dies that may be attached to a substrate. A die may be both electrically and mechanically coupled to a substrate using, for example, a flip-chip interconnect technique or by wirebonding in conjunction with a die-attach adhesive. A substrate may comprise one or more copper traces that may each be used as, e.g., a signal transmission line in the substrate. Any suitable methods may be used to form the copper traces, including, e.g., plating, electroplating, ink-jet printing. A copper trace may be covered with insulating material, e.g., dielectric material or any other substrate buildup material. The copper trace may be susceptible to copper migration and/or corrosion, e.g., during reliability test of the substrate. For example, copper atoms may migrate away from the copper trace under an electric field that is used in the reliability test. Under the reliability test condition, the insulating material be susceptible to moisture adsorption. The copper migration may lead to, e.g., short or open failure in a semiconductor package. Several factors may impact the copper migration, including, e.g., a width of a copper trace, a distance between adjacent copper traces, an intensity of the electric field, as well as other factors.

### BRIEF DESCRIPTION OF THE DRAWINGS

The invention described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

FIG. 1 is a schematic diagram of an embodiment of a semiconductor package.

FIGS. 2A to 2C are schematic diagrams of an embodiment of a method that may be used to form a passivation layer on a copper trace of a substrate.

FIG. 3 is a schematic diagram of a hypothesized atomic bonding configuration of the substrate of FIG. 2C.

FIG. 4 is a flow chart of an embodiment of a method that may be used to form a semiconductor package.

### DETAILED DESCRIPTION

In the following detailed description, references are made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numbers refer to the same or similar functionality throughout the several views.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

The following description may include terms, such as upper, lower, top, bottom, first, second, etc. that are used for descriptive purposes only and are not to be construed as limiting.

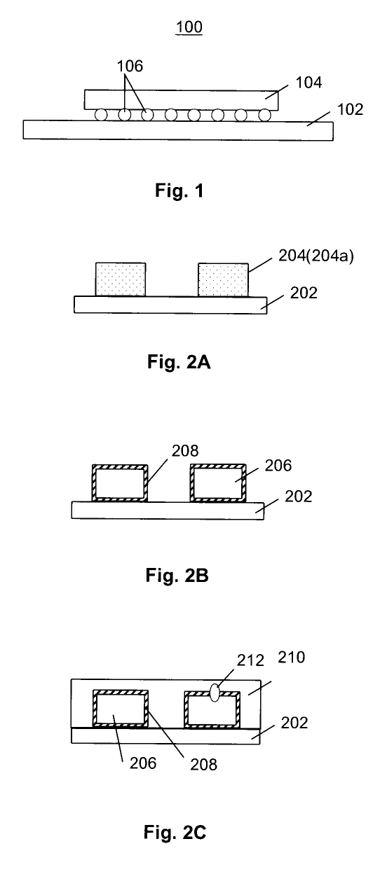

FIG. 1 illustrates an exemplary embodiment of a semiconductor package 100. The package 100 may comprise a substrate 102. A die 104 may be bonded to the substrate 102, e.g., on an upper side of the substrate 102. As shown in FIG. 1, the die 104 may comprise a bump die that may comprise one or more bumps 106 to couple the die 104 to the substrate 102; however, in some embodiments, any other interconnects may be utilized, including, e.g., gold stud bump, land grid arrays (LGA), ball grid arrays (BGA), conductive protrusions. While FIG. 1 illustrates a die 104 on the substrate 102, some embodiments may comprise more dies 104.

FIGS. 2A to 2C illustrate an exemplary embodiment of a method that may be used to form a passivation layer to prevent or reduce copper migration in a copper trace of a substrate. Referring to FIG. 2A, conductive paste 204 may be prepared. In one embodiment, the conductive paste 204 may comprise Cu particles that may have a size on a nanometer scale. The conductive paste 204 may further comprise Al nano particles that may have a weight ratio in a range from around 0.1% to around 5% in the conductive paste 204; however, in some embodiments, the Al nano particles may have a different weight ratio. For example, the concentration of the Al nano particles in the conductive paste 204 may be estimated based on a width of a copper line, a spacing between two adjacent copper lines, a thickness of a passivation layer to be formed and/or any other factors. In one embodiment, any suitable dispersant may be used to form the conductive paste 204. In another embodiment, the Cu nano particles and/or the Al nano particles may be formed, e.g., by reduction from solvent, grinding or any other suitable methods.

In one embodiment, the conductive paste 204 may be provided on substrate buildup material 202 to form one or more Al doped copper lines 204a. For example, the copper lines 204a may be printed on the substrate buildup material 202, e.g., through ink-jet printing. Referring to FIG. 2B, in one embodiment, the copper lines 204a may be sintered to form copper traces 206, e.g., at a temperature around 200° C. to around 300° C. for about 10 minutes to around 1 hour; however, in some embodiments, the copper lines 204a may be sintered to form one or more copper traces 206 under a different condition. For example, the sintering temperature may be determined based on, e.g., a melting point of the conductive paste 204, the Cu nano particles and/or the Al nano particles. In another embodiment, the copper lines 204a may be sintered in an inert environment.

In one embodiment, a diffusivity of an Al atom may be higher than that of a Cu atom. In another embodiment, an Al atom may have a higher reactivity with oxygen than that of a Cu atom. During sintering or any other thermal process, one or more Al atoms contained in a copper line 204a may diffuse or migrate to an outer surface of the copper line 204a to passivate the copper line 204a. For example, the migrated Al atoms may cover the copper lines 204a and one or more of the migrated Al atoms may be oxidized to form a barrier layer 208, e.g., Al₂O₃, on the copper lines 204a. For example, aluminum oxide may have a higher standard free energy than that of copper oxide.

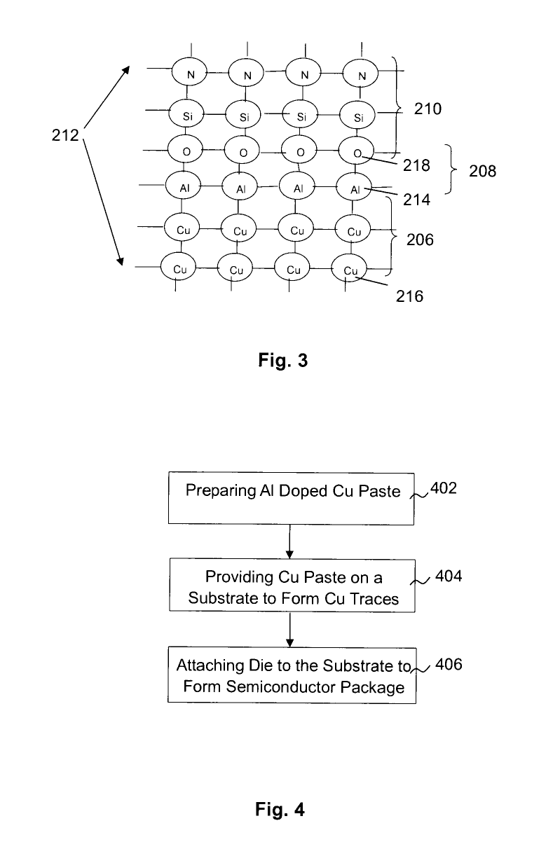

Referring to FIG. 2C, an insulating layer 210 may be provided on the copper traces 206 to insulate the copper traces 206. In one embodiment, the insulating layer 210 may comprise dielectric material or any other substrate buildup material. FIG. 3 shows an enlarged schematic diagram of atomic configuration at an interface 212 between a copper trace 206 and the insulating layer 210. Referring to FIG. 3, one or more Al atoms 214 may diffuse to cover one or more copper atoms 216 in a copper trace 206. One or more of the diffused Al atoms 214 that has not been oxidized during sintering may combine with oxygen atoms 218 in the insulating layer 210 to form, e.g., Al₂O₃, and thus a thickness of the barrier layer 208 may be increased. In one embodiment, the barrier layer 208 may bond a copper trace 206 to the insulating layer 210. In another embodiment, the barrier layer 208 may passivate a copper trace 206. Although FIG. 3 illustrates that the insulating layer 210 may comprise O, Si and N, in some embodiments, the insulating layer 210 may comprise any other elements. Although FIG. 2C illustrates a substrate is a single layered substrate, in some embodiments, the substrate may comprise multi layers.

FIG. 4 illustrates an exemplary embodiment of a method that may be used to provide a semiconductor package. Referring to FIG. 4, in block 402, a conductive paste may be prepared. In one embodiment, Cu nano particles may be mixed with Al particles that may have a size on a nanometer scale to form the conductive paste. In another embodiment, a weight ratio of Al nano particles in the conductive paste may be around 0.1% to around 5%; however, in some embodiments, different weight ratio may be applicable. For example, a weight ratio of the Al nano particles in the copper line may be determined based on a width of a copper line, a spacing between two copper lines, an amount of Al nano particles in the copper line that may migrate to an outer surface of the copper line, a thickness of the aluminum oxide film to be formed. However, in some embodiments, the weight ratio of the Al nano particles in the conductive paste may be estimated based on any other factors.

Referring to FIG. 4, in block 404, the conductive paste may be provided on a substrate to form one or more Al doped copper lines. A copper line may be sintered to form a copper trace. In one embodiment, any suitable method may be used to sinter a copper line, including, e.g., annealing. In another embodiment, during sintering, one or more Al atoms contained in a copper line may migrate to an outer surface of the copper line. One or more of the migrated Al atoms may react with oxygen atoms, e.g., in the sintering environment, to form, e.g., aluminum oxide at the outer surface of the copper line. In another embodiment, the copper traces may be covered with an insulating layer. One or more migrated Al atoms that have not oxidized may react with one or more oxygen atoms in the insulating layer to form aluminum oxide. In block 406, a die may be bonded to the substrate. For example, the die may be coupled to the substrate via one or more bumps, wire bonds, or any other interconnects.

While the methods of FIGS. 2A to 2C and FIG. 4 are illustrated to comprise a sequence of processes, the methods in some embodiments may perform illustrated processes in a different order. Further, while the embodiments as mentioned above comprise a certain number of dies, interconnects, substrates, copper traces or other component, some embodiments may apply to a different number. While the embodiments as mentioned herein may utilize copper traces that may be doped with aluminum, in some embodiments, any other suitable conductive materials may be used to form the conductive traces. For example, a conductive trace may be formed by a first conductive material that may be doped with a second conductive material. In one embodiment, the second conductive material may have a diffusivity that may be higher than that of the first conductive material. In another embodiment, the second conductive material may be oxidized to prevent or reduce migration of the first conductive material.

While certain features of the invention have been described with reference to embodiments, the description is not intended to be construed in a limiting sense. Various modifications of the embodiments, as well as other embodiments of the invention, which are apparent to persons skilled in the art to which the invention pertains are deemed to lie within the spirit and scope of the invention.

While certain features of the invention have been described with reference to embodiments, the description is not intended to be construed in a limiting sense. Various modifications of the embodiments, as well as other embodiments of the invention, which are apparent to persons skilled in the art to which the invention pertains are deemed to lie within the spirit and scope of the invention.

1. A semiconductor package, comprising:
a semiconductor die,
a substrate that is coupled to the die,
a trace formed in the substrate that comprises a first conductive material doped with a second conductive material, the first conductive material has a first diffusivity that is lower than a second diffusivity of the second conductive material to prevent migration of the first conductive material.

2. The semiconductor package of claim 1, wherein the first conductive material comprise copper and the second conductive material comprise aluminum.

3. The semiconductor package of claim 1, wherein the first conductive material has a first reactivity with oxygen that is lower than a second reactivity with oxygen of the second conductive material.

4. The semiconductor package of claim 2, comprising:
a barrier layer on an outer surface of the trace, wherein the barrier layer comprises aluminum oxide.

5. The semiconductor package of claim 1, wherein the trace is covered by a barrier layer that comprises an oxide of the second conductive material.

6. The semiconductor package of claim 1, comprising:
an insulating layer on the trace,
a barrier layer to bond the insulating layer to the trace, the barrier layer comprise an oxide of the second conductive material.

7. The semiconductor package of claim 2,
an insulating layer on the trace, and
aluminum oxide formed on an outer surface of the trace.

8. A method, comprising:
providing a copper paste that is doped with aluminum; and
sintering the copper paste to provide a barrier layer on a trace formed by the copper paste to prevent migration of the copper.

9. The method of claim 8, wherein the barrier layer comprises aluminum oxide.

10. The method of claim 8, wherein a weight ratio of the aluminum in the copper paste is around 0.1% to around 5%.

11. The method of claim 8, comprising:
sintering the copper paste under a temperature of around 200° C. to 300° C for around 10 minutes to one hour.

12. The method of claim 8, comprising:
mixing copper nano particles with aluminum nano particles to provide the copper paste.

13. The method of claim 8, comprising:
providing an insulating layer on the trace to increase a thickness of the barrier layer, wherein the insulating layer comprises oxygen.

14. The method of claim 8, wherein the barrier layer comprise aluminum oxide.

15. The method of claim 8, wherein the sintering is in an inert environment.
